(19) United States
(12) Patent Application Publication
(10) Pub. No.: US 2006/0118872 A1
(43) Pub. Date: Jun. 8, 2006

(54) Semiconductor device and method of manufacturing the same

(75) Inventor: Tatsushi Kato, Suwa-shi (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/298,136

(22) Filed: Dec. 8, 2005

(30) Foreign Application Priority Data
Dec. 8, 2004 (JP) 2004-355733
Sep. 9, 2005 (JP) 2005-262212

(51) Int. Cl. H01L 27/12

(52) U.S. Cl. 257/347

(57) ABSTRACT

A semiconductor device includes: a semiconductor layer portion provided on an insulating layer, the semiconductor layer portion becoming an element formation region; a gate insulating layer provided on the semiconductor layer portion; a gate electrode provided on the gate insulating layer; and an impurity region provided in the semiconductor layer portion, the impurity region becoming a source or drain region. The semiconductor layer portion is provided with a recess and an isolation insulating layer formed by filling the recess with an insulating material.

### BACKGROUND

1. Technical Field

The present invention relates to a semiconductor device having an SOI (‘silicon on insulator’) structure and a method of manufacturing the same.

2. Related Art

Recently, as compared with a semiconductor device (bulk type semiconductor device) directly formed on a bulk wafer in the related art, a semiconductor device having an SOI structure in which a parasitic capacitance can be reduced and which can be operated with a low voltage due to a low threshold voltage has been drawing attention. It is noted that the semiconductor device with the SOI structure herein means a semiconductor device having elements, such as insulating gate type field effect transistors, on a semiconductor layer provided on an insulating layer. In such a semiconductor device, since the insulating layer is formed below a thin semiconductor layer on which the elements are formed, the area that the elements are surrounded by the insulating layer becomes larger compared with the semiconductor device directly formed on the bulk wafer. When the semiconductor layer is a silicon layer and the insulating layer is a silicon oxide layer, the silicon oxide layer has approximately 100 times less heat conductivity than that of the silicon layer. Therefore, in a semiconductor device with the SOI structure, it is more difficult to dissipate heat than in a device on a bulk wafer, and it is likely to be affected by the self specific heat effect.

An example of a technology that prevents the self specific heat effect is disclosed in JP-A-8-316335. JP-A-8-316335 discloses a technology in which the heat dissipation is improved by forming an opening in a part of an insulating layer disposed below a semiconductor layer and by connecting a field effect type transistor with a silicon substrate below the insulating layer.

However, as described above, forming the opening in the insulating layer located below the semiconductor layer diminishes the effect that the original SOI structure has. Therefore, a semiconductor device which has a unique effect of the SOI structure and has an improved heat dissipation capacity has been demanded.

### SUMMARY

An advantage of some aspects of the invention is that it provides a semiconductor device, which has unique advantages of an SOI structure and has an improved heat dissipation capacity, and a method of manufacturing the same.

According to a first aspect of the invention, a semiconductor device includes: a semiconductor layer portion provided on an insulating layer, the semiconductor layer portion becoming an element formation region; a gate insulating layer provided on the semiconductor layer portion; a gate electrode provided on the gate insulating layer; and an impurity region provided in the semiconductor layer portion, the impurity region becoming a source or drain region. The semiconductor layer portion is provided with a recess and an isolation insulating layer formed by filling the recess with an insulating material.

In the semiconductor device according to the aspect of the invention, since the recess portion is provided on the semiconductor layer portion, the surface area of the semiconductor device can be increased compared with a semiconductor device composed of one semiconductor layer where element formation regions are continuous. Furthermore, since the recess is provided with the isolation insulating layer, the contact area between the semiconductor and the insulating material can be increased. Therefore, a semiconductor device with the improved heat dissipation capacity can be provided. This is because, for example, although the insulating layer such as silicon oxide layers is made of a material having lower heat conductivity compared with a silicon layer, heat dissipation is performed. Therefore, by increasing the contact area, the amount of heat dissipation is increased by that amount. As a result, heat dissipation can be facilitated, and the current drive capability by self heating and the like may be suppressed from being reduced. Also, the semiconductor device with an advantage of an SOI structure may be provided.

It is noted that in the above aspect of the invention, stating a specific ‘B layer’ provided on a specific ‘A layer’ means both the case when the B layer is provided directly on the A layer and the case when the B layer is provided on the A layer with another layer interposed therebetween.

Further, in the semiconductor device according to the first aspect of the invention, it is preferable that the insulating layer have a protrusion.

In the invention, the contact area between the semiconductor layer and the insulating layer can be increased corresponding to the size of the protrusion of the insulating layer disposed below the semiconductor layer, and thus heat dissipation capacity can be further improved.

According to a second aspect of the invention, a semiconductor device includes: a semiconductor layer portion provided on an insulating layer, the semiconductor layer portion becoming an element formation region; a gate insulating layer provided on the semiconductor layer portion; a gate electrode provided on the gate insulating layer; and an impurity region provided in the semiconductor layer portion, the impurity region becoming a source or drain region. The insulating layer has a protrusion on a surface being in contact with the semiconductor layer portion.

In the semiconductor device according to the above aspect of the invention, the contact area between the semiconductor layer portion and the insulating layer can be increased corresponding to the protrusion provided in the insulating layer. As a result, a semiconductor device with the same effect as the first semiconductor device can be provided. It is noted that, in the invention, the protrusion refers to a protruding shape formed in a direction in which the semiconductor layer portion is provided with reference to the insulating layer.

Further, in the semiconductor device according to the aspect of the invention, preferably, the insulating layer is provided on a predetermined substrate body and the insulating layer has a protrusion on a surface being in contact with the substrate body.

According to a third aspect of the invention, a semiconductor device includes: a first semiconductor layer portion provided on an insulating layer; a first insulating gate type field effect transistor provided on the first semiconductor layer portion; a first interlayer insulating layer provided at least on the first insulating gate type field effect transistor; a second semiconductor layer portion provided on the first interlayer insulating layer; a second insulating gate type field effect transistor provided on the second semiconductor layer portion; and a second interlayer insulating layer provided on the second insulating gate type field effect transistor. The sum of surface areas of the first semiconductor layer portion and the second semiconductor layer portion is larger than the surface area of one continuous semiconductor layer in another semiconductor device having an insulating gate type field effect transistor in an element formation region formed of the continuous semiconductor layer.

In the semiconductor device according to the third aspect of the invention, the insulating layer has the protrusion on the surface being in contact with the substrate body. Here, the protrusion refers to a protruding shape formed in a direction in which the substrate body is provided with reference to the insulating layer. Therefore, at the interface between the insulating layer and the substrate body, the contact area can be made larger. As a result, when the heat transferred from the semiconductor device spreads into the substrate body, it is possible to make the heat spread fast due to the large contact area. Therefore, it is possible to provide a semiconductor device having the same advantage as in the first semiconductor device.

According to a fourth aspect of the invention, a semiconductor device includes: a first semiconductor layer portion provided on an insulating layer; a first insulating gate type field effect transistor provided in the first semiconductor layer portion; a first interlayer insulating layer provided at least on the first insulating gate type field effect transistor; a second semiconductor layer portion provided on the first interlayer insulating layer; a second insulating gate type field effect transistor provided on the second semiconductor layer portion; and a second interlayer insulating layer provided on the second insulating gate type field effect transistor. The sum of the surface areas of the first semiconductor layer portion and the second semiconductor layer portion is larger than the surface area of one continuous semiconductor layer in another semiconductor device having an insulating gate type field effect transistor in an element formation region that is formed of the continuous semiconductor layer.

In the semiconductor device according to the fourth aspect of the invention, the semiconductor layer portion which is the element formation region is formed in a plurality of layers having different levels so that the sum of the surface areas of the first semiconductor layer portion and the second semiconductor layer portion is made larger. Therefore, the contact area between the semiconductor, such as the first and the second layer portions, and the insulator, such as the first and the second interlayer insulating layer, can be increased. As a result, a semiconductor device having the same effect as the first semiconductor device can be provided.

Further, in the semiconductor device according to the above aspect of the invention, preferably, at least one of the first and the second semiconductor layer portion can be provided with a recess and an isolation insulating layer made by filling an insulating material to the recess.

Furthermore, in the semiconductor device according to the above aspect of the invention, it is preferable that the insulating layer have a protrusion.

According to the aspect of the invention, the surface area can be further increased, and heat dissipation capacity can be further improved.

The semiconductor device according to the first to fourth aspects of the invention can take additional aspects described below.

In the semiconductor device according to the first to fourth aspects of the invention, the recess can be provided in a line shape and can cross the longitudinal direction of the gate electrode. Also, in such cases, in each of the semiconductor devices according to the invention, the recess can have a depth reaching the insulating layer.

According to this aspect, the element formation region is formed of a plurality of semiconductor layers isolated by the isolation insulating layers. Therefore, the contact area between the semiconductor layer portion and the insulator, such as the insulating layers, the isolation insulating layer, or the like, can be increased, and the thickness of the semiconductor layer can be made uniform. As a result, heat dissipation is facilitated. Also, since the thickness of the semiconductor layer provided below the gate insulating layer (where the channel is formed) is uniform, a semiconductor device capable of performing a stable operation can be provided.

In the semiconductor device according to the aspect of the invention, it is possible that the recess is provided in a line shape and does not cross the longitudinal direction of the gate electrode.

In the semiconductor device according to the aspect of the invention, the recess can be provided in a matrix.

In the semiconductor device according to the aspect of the invention, the protrusion can be provided in a line shape and cross the longitudinal direction of the gate electrode.

In the semiconductor device according to the aspect of the invention, it is possible that the protrusion is provided in a line shape and does not cross the longitudinal direction of the gate electrode.

In the semiconductor device according to the aspect of the invention, the protrusion can be provided in a matrix.

A method of manufacturing the semiconductor device according to the first aspect of the invention includes: forming a recess on a semiconductor layer portion which is an element formation region provided on an insulating layer; forming an isolation insulating layer on the recess; forming a gate insulating layer at least on the semiconductor layer portion; forming a gate electrode on the gate insulating layer; and forming an impurity region provided in the semiconductor layer, the impurity region becoming a source or drain region.

According to the method of manufacturing the semiconductor device of the aspect of the invention, the isolation insulating layer can be formed in the element formation region. As a result, the semiconductor device having a large contact surface between the semiconductor layer and the insulating layer can be manufactured.

The method of manufacturing the semiconductor device can take additional aspects described below.

In the method of manufacturing the semiconductor device according to the aspect of the invention, the forming of the recess on the semiconductor layer portion includes: preparing a substrate in which the semiconductor layer is provided on the insulating layer; and forming an opening, which becomes the element formation region, in the semiconductor layer. Forming the opening and the recess is performed by the same process.

According to this aspect, the forming of the opening and the recess can be performed without increasing the number of processes.

In the method of manufacturing the semiconductor device according to the aspect of the invention, the forming of the recess can be performed until the insulating layer is exposed.

Further, a method of manufacturing the semiconductor device according to the second aspect of the invention includes: preparing a semiconductor layer having a recess; filling the recess and forming an insulating layer on the semiconductor layer; providing a predetermined substrate body on the insulating layer to form an SOI substrate in which a surface, opposing the surface on which the recess is provided, of the semiconductor layer becomes a surface on which elements are formed; providing an element formation region on the semiconductor layer to form the semiconductor layer portion which is the element formation region; forming a gate insulating layer on the semiconductor layer portion; forming a gate electrode on the gate insulating layer; and forming an impurity region provided in the semiconductor layer portion, the impurity region becoming a source or drain region.

According to the method of manufacturing the semiconductor device according to the aspect of the invention, the semiconductor layer portion can be provided on the insulating layer formed with unevenness. Therefore, the surface being in contact with the insulating layer in the semiconductor layer portion has unevenness corresponding to the unevenness of the insulating layer, and thus the surface area can be increased. Therefore, the semiconductor device with an increased contact area between the insulating layer and the semiconductor layer portion can be manufactured.

### BRIEF DESCRIPTION OF THE DRAWINGS

The invention will be described with reference to the accompanying drawings, wherein like numbers reference like elements.

FIG. 1 is a view schematically showing a semiconductor device of a first embodiment.

FIG. 2 is a view schematically showing a process of a method of manufacturing the semiconductor device shown in FIG. 1.

FIG. 3 is a view schematically showing a process of the method of manufacturing the semiconductor device shown in FIG. 1.

FIG. 4 is a view schematically showing a process of the method of manufacturing the semiconductor device shown in FIG. 1.

FIG. 5 is a view schematically showing a process of the method of manufacturing the semiconductor device shown in FIG. 1.

FIG. 6 is a view schematically showing a semiconductor device according to a first modification.

FIG. 7 is a view schematically showing a process of a method of manufacturing the semiconductor device shown in FIG. 6.

FIG. 8 is a view schematically showing a semiconductor device according to a second modification.

FIG. 9 is a view schematically showing a process of the method of manufacturing the semiconductor device shown in FIG. 7.

FIG. 10 is a view schematically showing a semiconductor device according to a second embodiment.

FIG. 11 is a view schematically showing a process of a method of manufacturing the semiconductor device shown in FIG. 10.

FIG. 12 is a view schematically showing a process of the method of manufacturing the semiconductor device shown in FIG. 10.

FIG. 13 is a view schematically showing a process of the method of manufacturing the semiconductor device shown in FIG. 10.

FIG. 14 is a view schematically showing a process of the method of manufacturing the semiconductor device shown in FIG. 10.

FIG. 15 is a view schematically showing the semiconductor device according to a modification of the second embodiment.

FIG. 16 is a view schematically showing a process of a method of manufacturing the semiconductor device shown in FIG. 15.

FIG. 17 is a view schematically showing a process of the method of manufacturing the semiconductor device shown in FIG. 15.

FIG. 18 is a view schematically showing a process of the method of manufacturing the semiconductor device shown in FIG. 15.

FIG. 19 is a view schematically showing a process of the method of manufacturing the semiconductor device shown in FIG. 15.

FIG. 20 is a view schematically showing a semiconductor device according to a third embodiment.

FIG. 21 is a view schematically showing a process of a method of manufacturing the semiconductor device shown in FIG. 20.

FIG. 22 is a view schematically showing a process of the method of manufacturing the semiconductor device shown in FIG. 20.

FIG. 23 is a view schematically showing a process of the method of manufacturing the semiconductor device shown in FIG. 20.

FIG. 24 is a view schematically showing a process of the method of manufacturing the semiconductor device shown in FIG. 20.

FIG. 25 is a view schematically showing a conventional semiconductor device.

FIG. 26 is a view schematically showing the semiconductor device according to the embodiment.

FIG. 27 is a view schematically showing the semiconductor device according to a comparative example.

FIG. 28 is a view showing results of the embodiment and the comparative example.

### DESCRIPTION OF EXEMPLARY EMBODIMENTS

Hereinafter, an embodiment of the invention will be described.

### First Embodiment

Semiconductor Device

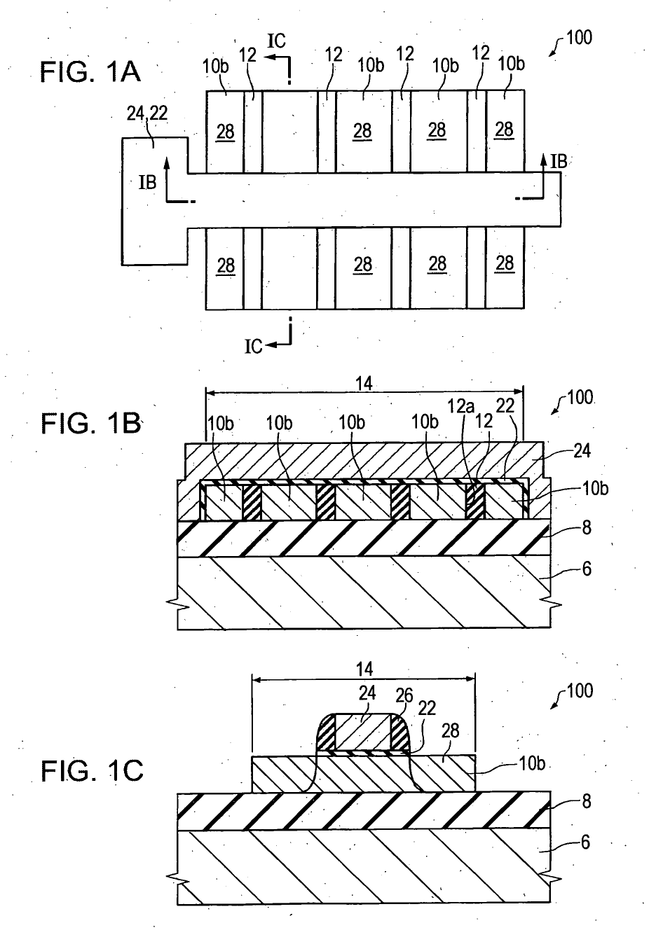

First, a semiconductor device according to a first embodiment will be described with reference to FIG. 1. FIG. 1A is a plan view schematically showing the positional relationship between a semiconductor layer portion and a gate electrode in the semiconductor device of the first embodiment, and FIG. 1B is a cross-sectional view taken along the line IB-IB of FIG. 1A, and FIG. 1C is a cross-sectional view taken along the line IC-IC of FIG. 1A.

As shown in FIGS. 1A to 1C, first, the semiconductor device of the first embodiment includes, on a supporting substrate 6, an insulating layer (silicon oxide layer) 8 and a semiconductor layer portion 10 in which an element formation region 14 is defined. The semiconductor layer portion 10 can be, for example, a single-crystal silicon layer, an amorphous silicon layer, a poly-crystal silicon layer, a silicon-germanium layer, and the like. In the following description, a case in which a silicon layer is used as the semiconductor layer portion 10 and a silicon oxide layer is used as the insulating layer will be described as an example.

The element formation region 14 includes an isolation insulating layer 12 and a semiconductor layer portion 10 having a plurality of semiconductor layers 10b isolated by the isolation insulating layer 12 in island shapes. In other words, the isolation insulating layer 12 is provided in the semiconductor layer portion 10. The isolation insulating layer 12 is formed by filling an insulating material in a recess 12a having a depth reaching the insulating layer 8. In FIG. 1, a case in which the isolation insulating layer 12 is provided in a line shape so as to cross the longitudinal direction of a gate electrode 24. Also, for example, a silicon oxide layer may be used as a material for the isolation insulating layer 12.

In the element formation region 14, each of the island-shaped semiconductor layers 10b is provided with an isolated gate type field effect transistor 20a (hereinafter referred to as a “transistor”). Each transistor 20a is formed by having at least a gate insulating layer 22 provided on the semiconductor layers 10b, the gate electrode provided on the gate insulating layer 22, a side wall insulating layer 26 provided on the side of the gate electrode 24, and an impurity region 28 provided in the semiconductor layers 10b. The gate electrode 24 is formed by patterning a single continuous conductive layer so that a plurality of transistors 20a can function as a single transistor 20. The impurity region 28 becomes a source or drain region. As shown in FIGS. 1B and 1C, the gate insulating layer 22, like the gate electrode 24, is provided continuously on the semiconductor layers 10b and the isolation insulating layer 12.

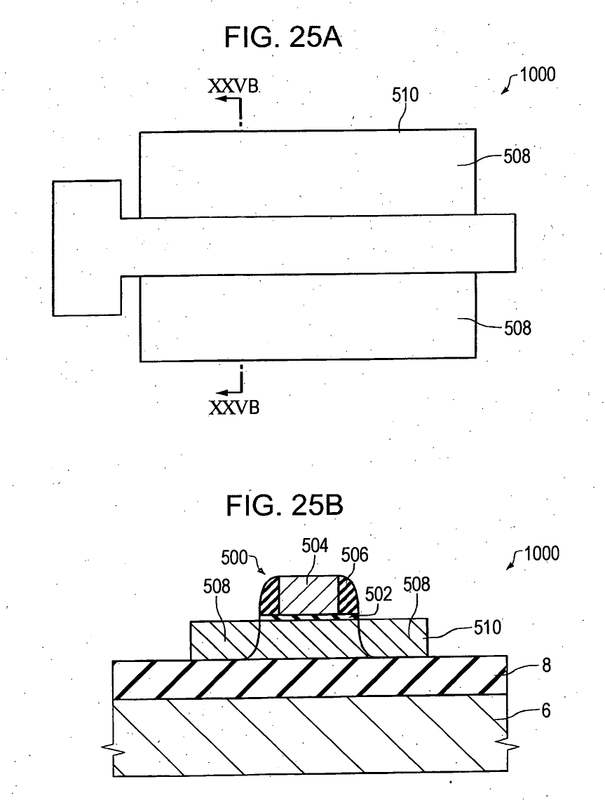

According to the semiconductor device 100 of the present embodiment, by providing the isolation insulating layer 12 on the semiconductor layer portion 10, the contact area between the semiconductor layer portion 10 and the insulating material can be increased. The increase of the contact area will be further described with reference to FIG. 25.

FIG. 25A is a view schematically showing a surface, corresponding to FIG. 1A, in a semiconductor device 1000 of the related art, and FIG. 25B is a cross-sectional view taken along the line XXVB-XXVB of FIG. 25A. The structure of a transistor 500 of the semiconductor device 1000 is the same as the transistor 20. Therefore, the surface area of the semiconductor layer portion 10 where a channel is formed (the surface area of the semiconductor layer portion 510 with the gate insulating layer thereon) in the semiconductor device 1000 is approximately equal to the sum of the surface areas where channels are formed in the semiconductor device 100. However, as can be seen by comparing FIG. 1B with FIG. 25B, as compared with the semiconductor layer portion 510, the surface area of the semiconductor layer portion 10 becomes larger by the amount that the recess 12a is provided, and thus the area being in contact with the insulating layer can be increased. In other words, the increase in the contact area herein means that, as compared with a case in which the surface area of the semiconductor layer in the region where channels are formed are the same as the area being in contact with the gate insulating layer in the semiconductor layer, the area being in contact with the insulating layer can be increased (in the same manner as in the other embodiments to be described below).

The silicon oxide layer is made of a material having lower heat conductivity compared with the silicon layer but heat dissipation is achieved, so that the heat dissipation capacity can be improved by increasing the contact area. As a result, the heat dissipation can be facilitated, deterioration in the current driving capability and the like may be prevented, and a semiconductor device having advantages of the SOI structure can be provided.

Method of Manufacturing Semiconductor Device

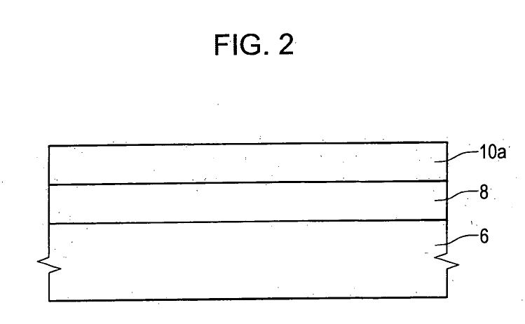

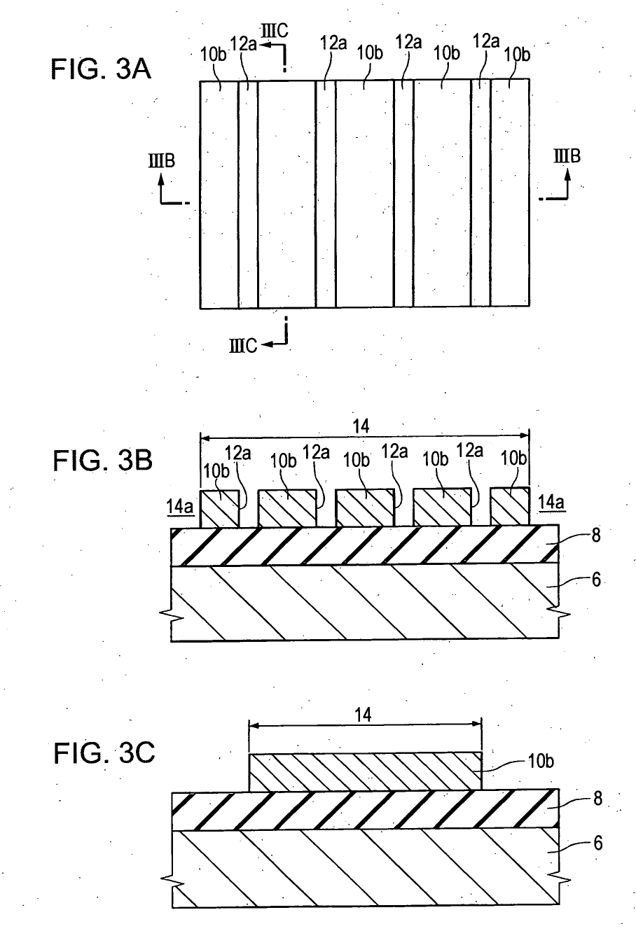

Next, a method of manufacturing the semiconductor device according to the present embodiment will be described with reference to FIGS. 2 to 5. FIGS. 2 to 5 are views showing a process of method of manufacturing the semiconductor device according to the present embodiment, i.e., FIG. 2 shows a cross-sectional view corresponding to FIG. 1C, and FIGS. 3A to 3C, 4A to 4C, and 5A to 5C show cross sections corresponding to FIGS. 1A to 1C, respectively.

In the manufacturing method according to the present embodiment, first, an SOI substrate is prepared. As shown in FIG. 2, the present embodiment illustrates an example in which, as the SOI substrate, an insulating layer 8 is provided on the supporting substrate 6, and a semiconductor layer 10a is provided on the insulating layer 8. The materials described above can be used for the semiconductor layer 10a.

Next, as shown in FIG. 3, an element formation region 14 is defined, and a recess 12a for an isolation insulating layer 12 to be formed at a later process is formed. The element formation region 14 is defined by removing a predetermined region of the semiconductor layer 10a until the insulating layer 8 is exposed to form an opening portion 14a. Also, the recess 12a is formed by making a mask layer (not shown) so as to overlay the region where the recess 12a is not to be formed, and then removing the semiconductor layer 10a. In the semiconductor device of the present embodiment, since the depths of the opening portion 14a and the recess 12a are the same, the opening portion 14a and the recess 12a can be made by a single process. In other words, the semiconductor layer 10a may be removed by using a mask layer (not shown) having openings on the region where the opening portion 14a and the recess 12a are formed. Removal of the semiconductor layer 10a may be performed by using technologies such as the well-known wet etching or the dry etching or the like depending on the material thereof.

Thereby, the element formation region 14 is defined, and the recess 12a for forming the isolation insulating layer 12 is formed. In other words, the semiconductor layer portion 10 composed of the plurality of island-shaped semiconductor layers 10b is formed. In the present embodiment, an example of forming the line-shaped recess 12a is illustrated which has the depth reaching the insulating layer 8.

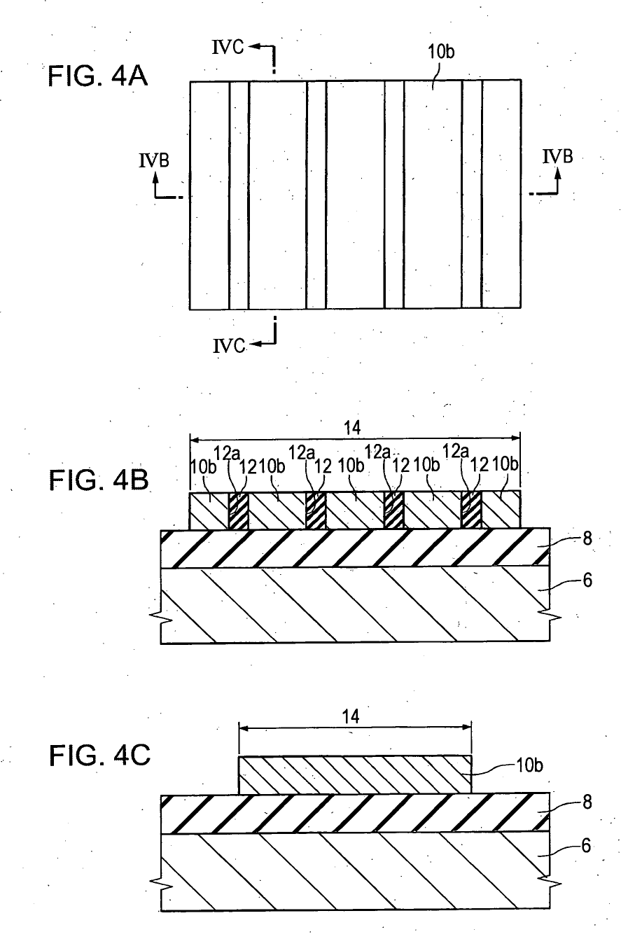

Next, as shown in FIG. 4, the isolation insulating layer 12 is formed in the recess 12a. The isolation insulating layer 12 is formed by, for example, forming an insulating layer (not shown) so as to overlay the semiconductor layer 10 including the recess 12a and by removing the insulating layer until the surface of the semiconductor layer 10 is exposed. The insulating layer may be, for example, a silicon oxide layer.

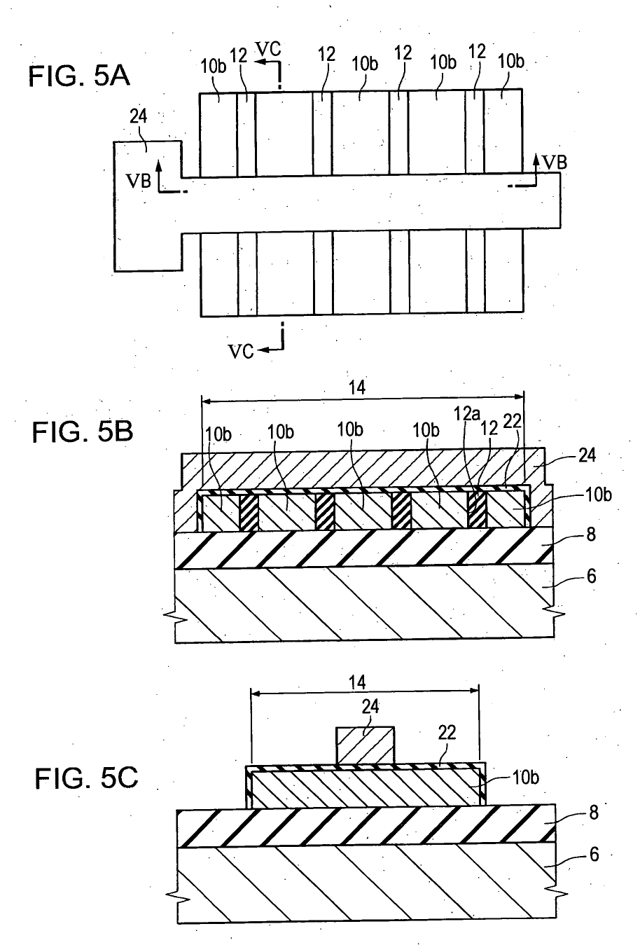

Next, as shown in FIG. 5, a gate insulating layer 22 is formed on the semiconductor layer portion 10. The gate insulating layer 22 may be formed by, for example, the thermal oxidation technique. Finally, a gate electrode 24 is formed on the gate insulating layer 22. The gate electrode 24 is formed by, for example, forming a conductive layer on the entire surface and then by patterning the conductive layer.

Finally, as shown in FIG. 1, a side wall insulating layer 26 is formed on side surfaces of the gate electrode 24. Thereafter, a predetermined conductive impurity is injected into the semiconductor layer 10 so as to form an impurity region 28 which becomes a source or drain region. The injection of impurity maybe accomplished, for example, by the ion injection technique.

By the above process, the semiconductor device of the present embodiment may be manufactured.

According to the manufacturing method of the present embodiment, the isolation insulating layer 12 may be formed in the element formation region 14. Therefore, in the element formation region 14, the contact area between the semiconductor layer portion 10 and the insulator, such as the insulating layer 8, the isolation insulating layer 12 and the like, can be increased by the amount that the isolation insulating layer 12 is provided. As a result, the semiconductor device having the effect described above can be provided.

Even though the case in which the semiconductor layer portion 10 is formed of the plurality of the island-shaped semiconductor layers 10b has been described in the present embodiment, the invention is not limited thereto. For example, the bottom surface of the isolation insulating layer 12 may not reach the insulating layer 8.

### Variation of Embodiment Modifications

### First Modification

Next, a modification of the semiconductor device of the present embodiment will be described. It is noted that, in the following description, different features from the above-described embodiment will be described.

Semiconductor Device

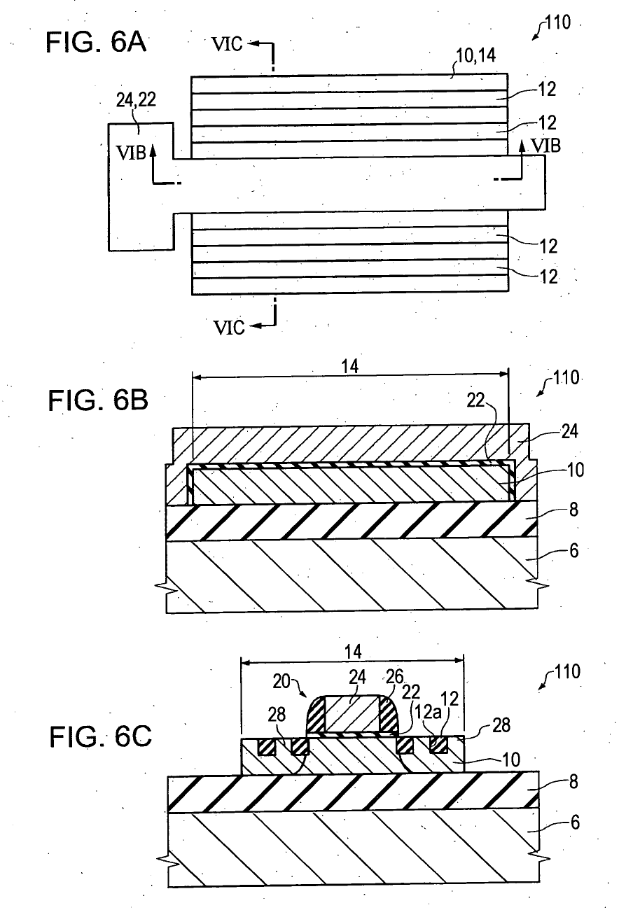

FIG. 6 shows a semiconductor device according to a first modification, i.e., FIGS. 6A to 6C are views showing plan or sectional views corresponding to FIGS. 1A to 1C, respectively. The semiconductor device 110 according to the first modification is an example in which the isolation insulating layer 12 is disposed in a manner different from the semiconductor device 100 of the above-described embodiment.

As shown in FIGS. 6B and 6C, the semiconductor device 110 is provided with a transistor 20 on the semiconductor layer portion 10 which is the element formation region 14. The semiconductor layer portion 10 is provided with a line-shaped isolation insulating layer 12 that extends parallel to the longitudinal direction of the gate electrode 24. In other words, in the semiconductor layer portion 10, the thickness of a portion where the isolation insulating layer 12 is different from the thickness of a portion where the isolation insulating layer 12 is not provided. In other words, the top surface of the semiconductor layer portion 10 has unevenness. As such, when the isolation insulating layer 12 is provided parallel to the longitudinal direction of the gate electrode 24, the isolation insulating layer 12 needs to be placed so as not to be provided in the semiconductor layer portion 10 which will become a channel region (below the gate isolation layer 22). Also, when the bottom of the isolation insulating layer 12 reaches the insulating layer 8, the impurity region 28 that will become a source or drain region is separated, thereby increasing the resistance. Therefore, the isolation insulating layer 12 needs to be provided so that the bottom does not reach the insulating layer 8.

Method of Manufacturing Semiconductor Device

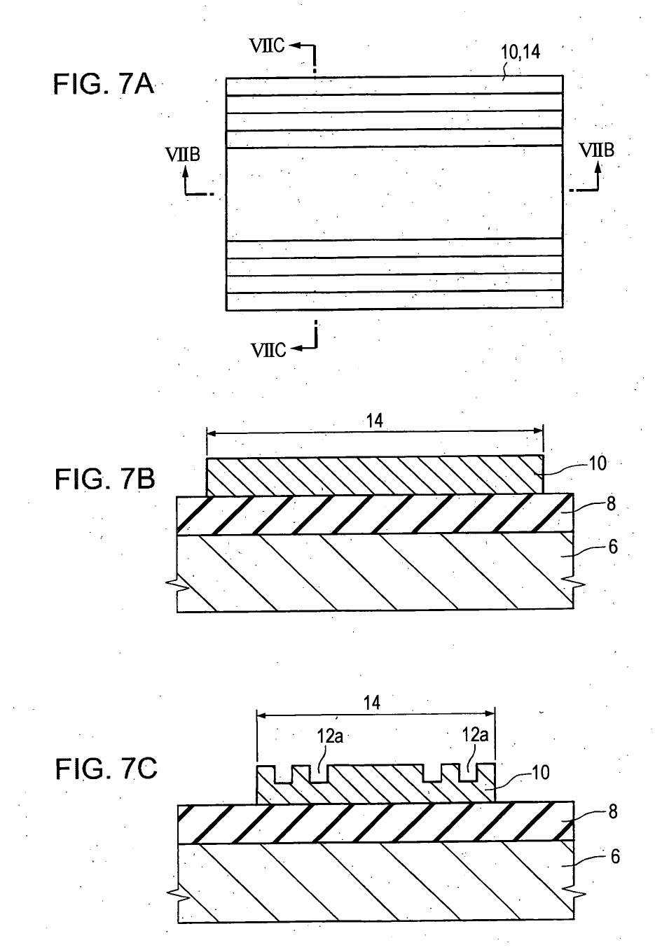

Next, a method of manufacturing the semiconductor device 110 shown in FIG. 6 will be described with reference to FIG. 7. First, by performing the same process as in the above-described embodiment, an SOI substrate is prepared. Next, an element formation region 14 is defined. More specifically, a mask layer (not shown) overlaying at least the element formation region 14 is formed, and then the semiconductor layer 10a is etched. At that time, the removal of the semiconductor layer 10a is performed until the insulating layer 8 is exposed. Thereafter, the mask layer is removed.

Thereafter, as shown in FIG. 7, a recess 12a is formed at the region where the isolation insulating layer 12 is formed. Forming the recess 12a is accomplished by forming a mask layer (not shown) having an opening in the region on the semiconductor layer portion 10 where the recess 12a will be formed and then by removing the semiconductor layer portion 10. The recess 12a is formed so that the bottom does not reach the insulating layer 8. Thereafter, by performing the same process as in the embodiment, the isolation insulating layer 12 is formed in the recess 12a.

Finally, by performing the same processes as in the embodiment, the transistor 20 is formed, thereby forming the semiconductor device 110.

According to the semiconductor device 110 of the first modification, in the element formation region 14, the contact area between the surface of the semiconductor layer portion 10 and the insulator, such as the insulating layer 8, the isolation insulating layer 12, and the like, may be increased by the amount that the isolation insulating layer 12 is provided. Therefore, semiconductor devices having the same effect as in the semiconductor device 100 can be provided.

It is noted that the modification has exemplified the case in which the element formation region 14 is first defined and then the recess 12a is formed. However, the invention is not limited thereto, i.e., the recess 12a may be formed first and then the element formation region 14 may be defined. Also, if it is not necessary to remove the semiconductor layer 10a until the insulating layer 8 is exposed when the element formation region 13 is defined, the element formation region 13 may be defined in the same process as the recess 12a is formed.

### Second Modification

Next, a semiconductor device according to a second modification will be described.

Semiconductor Device

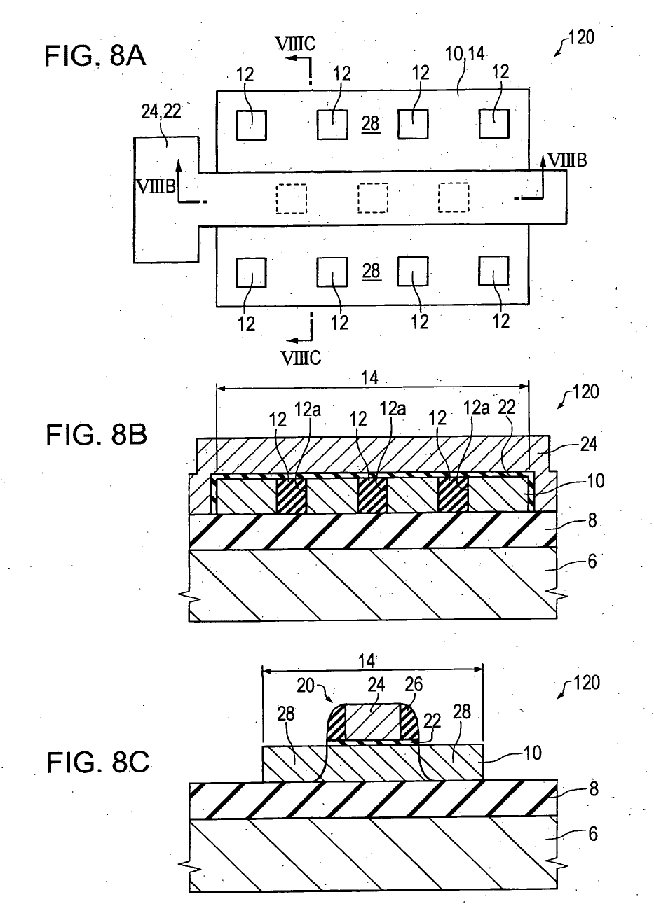

FIG. 8 shows a semiconductor device 120 according to the second modification, i.e., FIGS. 8A to 8C are views illustrating plan or section views corresponding to FIGS. 1A to 1C, respectively. The semiconductor device 120 according to the second modification is an example in which the isolation insulating layer 12 is disposed in a manner different from the semiconductor device 100 according to the above-described embodiment.

In the semiconductor device 120, as shown in FIGS. 8B and 8C, the semiconductor layer portion 10, which is the element formation region 14, is provided with the transistor 20. The semiconductor layer portion 10 is provided with the island-shaped isolation insulating layer 12 in a matrix. Also, although the present embodiment illustrates the isolation insulating layer 12 which is placed in a matrix, it may also be placed at random.

Method of Manufacturing Semiconductor Device

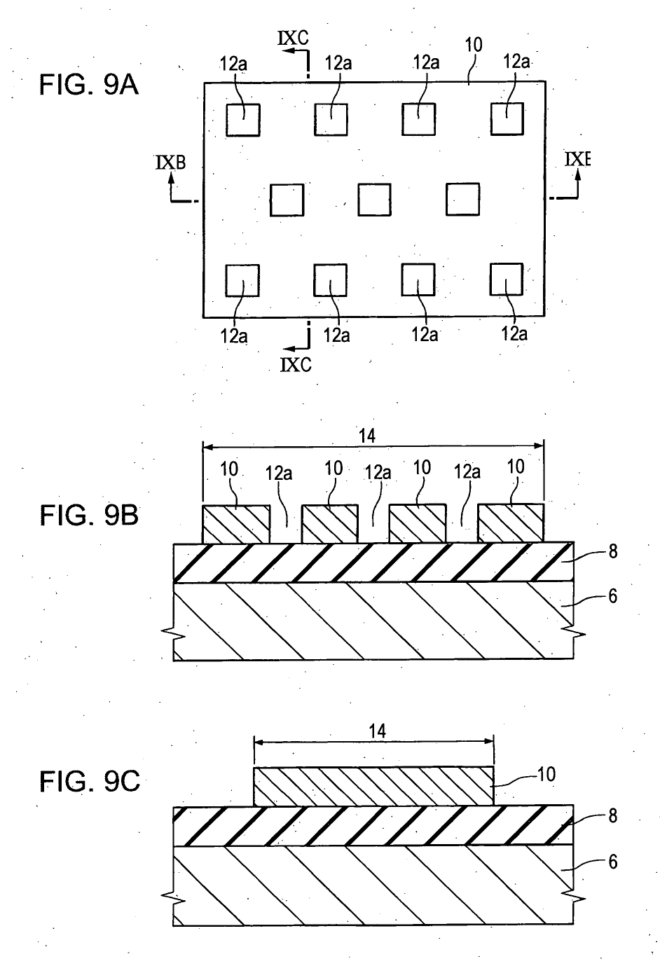

Next, a method of manufacturing the semiconductor device 120 shown in FIG. 8 will be described with reference to FIG. 9. First, similar to the process in the above-described embodiment, an SOI substrate is prepared. Thereafter, as shown in FIG. 9, an element formation region 14 is defined, and a recess 12a for forming an isolation insulating layer 12 is formed. More specifically, a mask layer (not shown) overlaying the area which is on the element formation region 14 and in which the isolation insulating layer 12 is not formed, is formed and then the semiconductor layer 10a is etched. At that time, removal of the semiconductor layer 10a is performed until the insulating layer 8 is exposed. Thereafter, the mask layer is removed. Through the process, the element formation region 14 is defined and the recess 12a is formed.

Finally, by performing the same process as in the embodiment, the isolation insulating layer 12 is formed in the recess 12a. Thereafter, by performing the same processes as in the embodiment, the transistor 20 is formed, thereby forming the semiconductor device 120.

According to the semiconductor device 120 of the second modification, by providing the isolation insulating layer 12, the area where the surface of the semiconductor layer portion 10 is in contact with the insulator can be increased. As a result, a semiconductor device having the improved heat dissipation capacity can be provided.

In the second modification, the isolation insulating layer 12 reaches the insulating layer 8, however, the invention is not limited thereto. Thus, as in the first modification, the isolation insulating layer 12 may not reach the insulating layer 8. In such cases, the definition of the element formation region 14 and the formation of the recess 12a may be performed by a separate process, respectively.

### Second Embodiment

Next, the second embodiment will be described.

Semiconductor Device

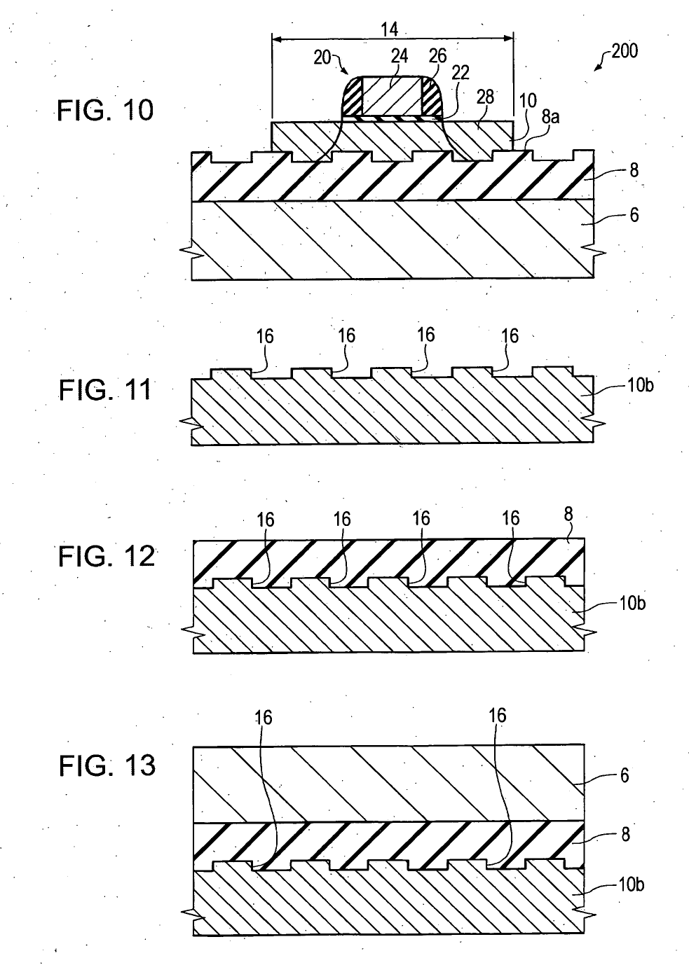

First, a semiconductor device according to a second embodiment will be described with reference to FIG. 10. FIG. 10 is a cross-sectional view schematically showing the semiconductor device 200 according to the second embodiment. The semiconductor device 200 is an example in which the shapes of the insulating layer 8 and the semiconductor layer 10 are different from those in the semiconductor device according to the first embodiment.

As shown in FIG. 10, in the semiconductor device 200 according to the embodiment, a semiconductor layer portion 10, which is an SOI layer, is provided with a transistor 20. The semiconductor layer portion 10 is provided on an insulating layer (silicon oxide layer) 8 which is on a supporting substrate 6. Also, the materials described above can be used for the semiconductor layer portion 10.

In the semiconductor device 200, the height of the top surface of the insulating layer 8 is not uniform, and the insulating layer 8 has a protrusion 8a. On the other hand, the position (height) of the top surface of the semiconductor layer portion 10 provided on the insulating layer 8 is approximately uniform. Therefore, the thickness of the semiconductor layer portion 10 located on the protrusion 8a is thinner than the thickness of the semiconductor layer portion 10 located on the insulating layer 8. In other words, in the semiconductor layer portion 10, the surface being in contact with the insulating layer 8 forms unevenness corresponding to the unevenness of the insulating layer 8. In the element formation region 14, the protrusion 8a may be line-shaped or matrix-shaped.

The transistor 20 includes a gate insulating layer 22 provided at least on the semiconductor layer portion 10, a gate electrode 24 provided on the gate insulating layer 22, a side wall insulating layer 26 provided on the side surfaces of the gate electrode 24, and an impurity region 28 provided in the semiconductor layer portion 10. The impurity region 28 becomes a source or drain region.

According to the semiconductor device 200 of the second embodiment, by providing the protrusion 8a, the surface of the semiconductor layer portion 10 being in contact with the insulating layer 8 has the unevenness, and accordingly, the surface area can be increased. Thereby, the contact area between the semiconductor layer portion 10 and the insulating material is increased. As a result, according to the semiconductor device 200 of the present embodiment, in the same manner as in the semiconductor device 100 of the first embodiment, the semiconductor device 200 with the improved heat dissipation capacity may be provided.

Method of Manufacturing Semiconductor Device

Next, the method of manufacturing the semiconductor device shown in FIG. 10 will be described with reference to FIGS. 11 to 14. FIGS. 11 to 14 are cross-sectional views schematically showing the process of manufacturing the semiconductor device shown in FIG. 10.

First, as shown in FIG. 11, the semiconductor device layer 10b whose surface height is not uniform is prepared. More specifically, since the semiconductor layer 10b has the recess 16, the surface height of the semiconductor layer 10b is not uniform. The semiconductor layer 10b become a parts of the semiconductor layer portion 10 (see figures) through the later process.

Next, as shown in FIG. 12, the recess 16 in the semiconductor layer 10b is filled, and then an insulating layer 8 is formed so as to overlay the semiconductor layer 10b. If necessary, a planarization process may be performed so that the surface of the insulating layer 8 becomes uniform. Through this process, the insulating layer 8 whose thickness varies depending on the recess 16 may be formed.

Next, as shown in FIG. 13, a substrate body 6 which will become a supporting substrate is provided on the insulating layer 8. The substrate body 6 may be, for example, a silicon substrate. The substrate body 8 can be bonded to the insulating layer 8 by overlaying the substrate body 6 on the insulating layer 8 and by performing a thermal treatment for the purpose of causing a chemical bonding at the connecting interface. Finally, the surface that opposes the surface being in contact with the insulating layer 8 of the semiconductor layer 10b is turned facing up, the thickness of the semiconductor layer 10b is thinned, thereby forming the semiconductor layer 10a with a desired thickness. More specifically, the thickness of the semiconductor layer 10b may be adjusted by polishing or etching the semiconductor layer 10b, or by performing a thinning process using hydrogen ion injection.

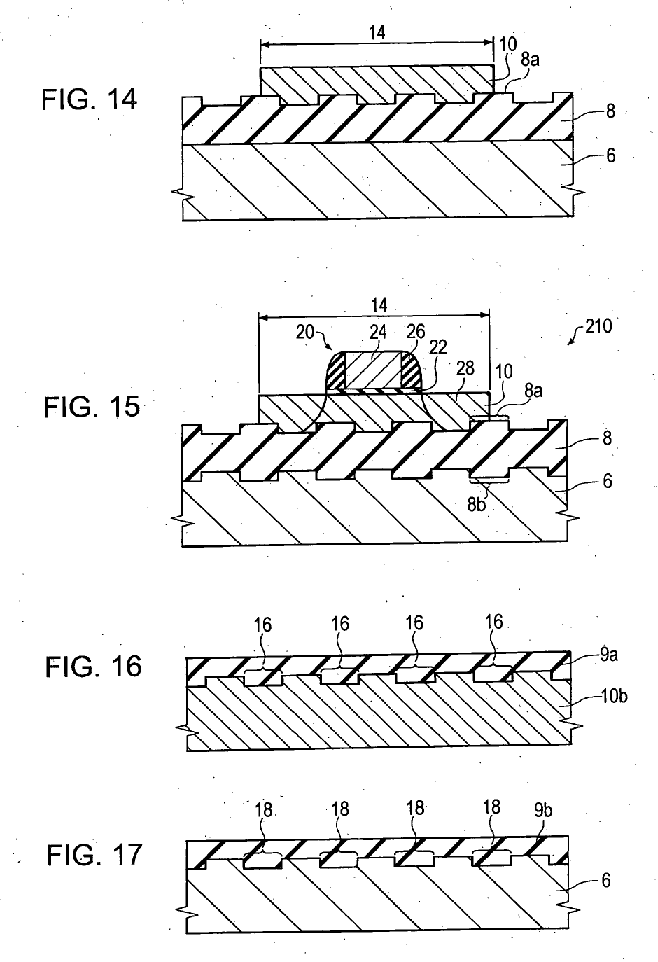

Next, as shown in FIG. 14, by removing the desired region in the semiconductor layer 10a, the semiconductor layer portion 10 which is the element formation region 14 is formed.

Finally, a transistor 20 (refer to FIG. 10) is formed in the semiconductor layer portion 10. Forming the transistor 20 may be accomplished in the same manner as the processes of the first embodiment.

According to the manufacturing method of the second embodiment, the semiconductor layer portion 10 may be formed with unevenness at the face of the surface being in contact with the insulating layer 8. Therefore, the surface area of the semiconductor layer portion 10 can be increased, and thus the contact surface of the semiconductor layer portion 10 and the insulating material (insulating layer 8) can be increased.

### Modification

Semiconductor Device

Next, a modification of a semiconductor device according to the second embodiment will be described with reference to FIG. 15. FIG. 15 is a cross-sectional view schematically showing the semiconductor device of the modification. The modification is different from the above-described embodiment in that the surface being in contact with the semiconductor layer 10 and the surface being in contact with the supporting substrate 6 in the insulating layer 8 are provided with unevenness, respectively. In the following description, the difference from the above-described embodiment will be explained.

As shown in FIG. 15, in the semiconductor device 210 according to the modification, a semiconductor layer portion 10, which is an SOI layer, is provided with a transistor 20. The semiconductor layer portion 10 is provided on the insulating layer (silicon oxide layer) 8 which is provided on the supporting substrate 6.

In the semiconductor device 210, the height is not uniform at the top surface (surface being in contact with the semiconductor layer portion 10) and the bottom surface (surface being in contact with the supporting substrate 6) of the insulating layer 8. The insulating layer 8 has a protrusion 8a with regard to the semiconductor layer portion 10, and a protrusion 8b with regard to the supporting substrate 6. In other words, in the semiconductor layer portion 10, the surface being in contact with the insulating layer 8 has unevenness corresponding to the unevenness of the insulating layer 8. Likewise, in the supporting substrate 6, the surface being in contact with the insulating layer 8 has unevenness corresponding to the shape of the protrusion 8b. In the element formation region 14, the protrusions 8a and 8b may also be line-shaped or matrix-shaped.

According to the semiconductor device 210 of the modification, by providing the protrusion 8a, the surface of the semiconductor layer portion 10 being in contact with the insulating layer 8 has unevenness, and thus the surface area can be increased. Furthermore, by providing the protrusion 8b, the area in which the supporting substrate 6 is in contact with the insulating layer 8 can be increased. Therefore, when the heat generated in the channel region dissipates from the insulating layer 8 to the supporting substrate 6, heat dissipation can be facilitated. As a result, according to the semiconductor device of the modification, the semiconductor device 210 with the improved heat dissipation capacity can be provided.

Method of Manufacturing Semiconductor Device

Next, a method of manufacturing the semiconductor device according to the modification will be described with reference to FIGS. 16 to 19. FIGS. 16 to 19 are cross-sectional views schematically showing the method of manufacturing the semiconductor device according to the modification.

First, as shown in FIG. 16, a semiconductor layer 10b whose surface height is uniform is formed. More specifically, a semiconductor layer (not shown), such as a silicon substrate, is prepared, and a mask layer (not shown) having a predetermined pattern is formed. Thereafter, the semiconductor layer not covered by the mask layer is etched. Through the process, as shown in FIG. 11, the semiconductor layer 10b having a recess 16 can be formed. Finally, by performing the same process as in the embodiment described above, the insulating layer 9a is formed on the semiconductor layers 10b.

Next, as shown in FIG. 17, a supporting substrate 6 whose surface height is not uniform is formed. The supporting substrate 6 can be a silicon substrate. Thereafter, by performing the same process described above, a recess 18 is formed, and thus the supporting substrate 6 whose surface height is not uniform can be formed. Finally, by performing the same process as in the embodiment described above, an insulating layer 9b is formed on the supporting substrate 6. The portion filled by the recess 18 in the insulating layer 9b becomes the protrusion 8b with respect to the supporting substrate 6.

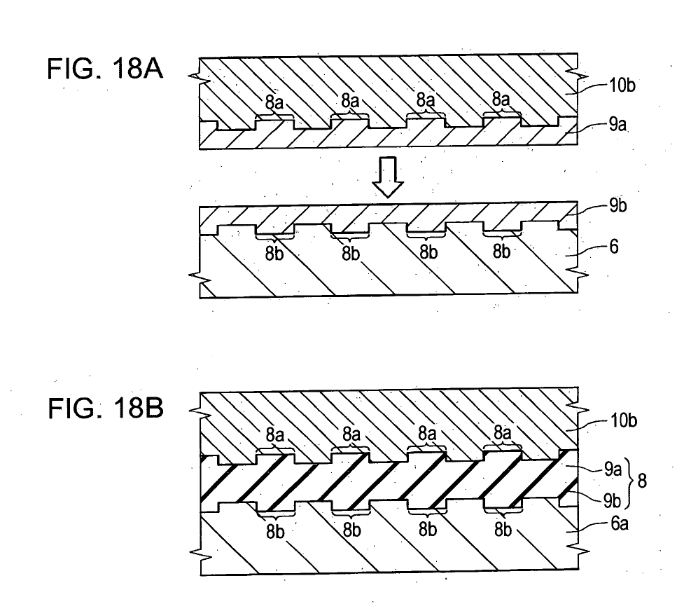

Next, as shown in FIG. 18A, the semiconductor layer 10b and the supporting substrate 6 are bonded to each other such that the insulating layer 9a and the insulating layer 9b are opposite to each other. The bonding can be accomplished by, for example, press-bonding these two substrates. Through the process, as shown in FIG. 18B, a substrate including the supporting substrate 6, the insulating layer 8 obtained by laminating the insulating layer 9a and 9b, and the semiconductor layers 10b can be formed.

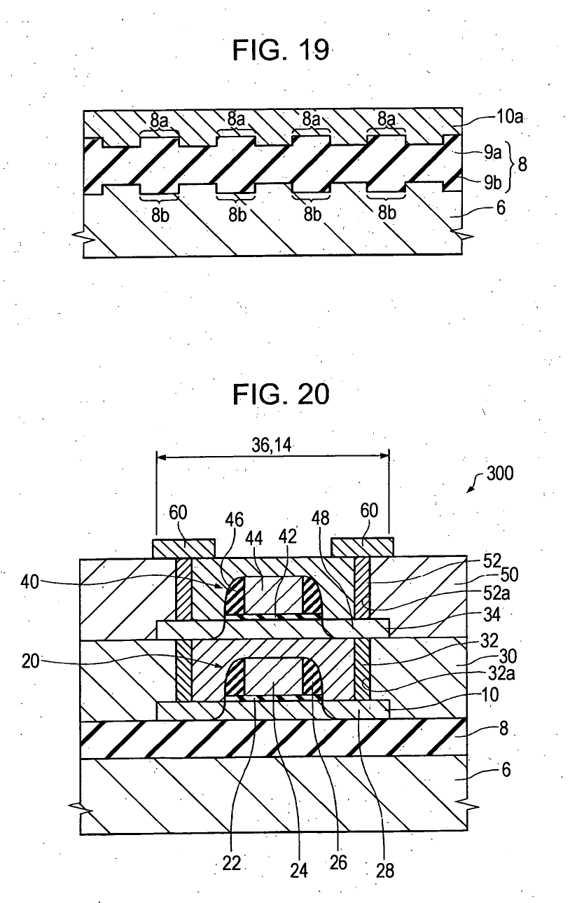

Next, by performing the process in the embodiment described above, the semiconductor layers 10b is thinned, thereby forming a semiconductor layer 10a having a desired layer thickness, as shown in FIG. 19. Finally, an element formation region 14 and a transistor 20 are formed by the same method described above. By the process above, the semiconductor device of the modification can be manufactured.

### Third Embodiment

Semiconductor Device

Next, a semiconductor device according to a third embodiment will be described with reference to FIG. 20. FIG. 20 is a cross-sectional view schematically showing a semiconductor device 300 according to the third embodiment.

The semiconductor device 300 according to the third embodiment is an example in which a first transistor 20 and a second transistor 40 are laminated.

As shown in FIG. 20, the semiconductor device 300 according to the third embodiment is provided with the first transistor 20 in a first semiconductor layer portion 10 which is an SOI layer. The semiconductor layer portion 10 is provided on an insulating layer (silicon oxide layer) which is provided on a supporting substrate 6. The materials described in the above embodiments can be used for the semiconductor layer portion 10.

The first transistor 20 includes a gate insulating layer 22 provided on the first semiconductor layer portion 10, a gate electrode 24 provided on the gate insulating layer 22, a side wall insulating layer 26 provided on the side surfaces of the gate electrode 25, and an impurity region 28 which is provided in the first semiconductor layer portion 10 and becomes the source or drain region.

A first interlayer insulating layer 30 is provided on the first semiconductor layer portion 10 and the insulating layer 8 which is exposed, so as to overlay the fist transistor 20. A second semiconductor layer portion 34 is provided on the first interlayer insulating layer 30. The second transistor 40 is provided on the second semiconductor layer portion 34. The second transistor 40 includes a gate insulating layer 42, a gate electrode 44 provided on the gate insulating layer 42, a side wall insulating layer 46 provided on the side surfaces of the gate electrode 44, and an impurity region 48 provided in the second semiconductor layer portion 34. The impurity region 48 becomes a source or drain region. A second interlayer insulating layer 50 is provided on the second transistor 40.

A contact layer 32 is provided in the first interlayer insulating layer 30 to connect the impurity region 28 of the first transistor 20 to the impurity region 48 of the second transistor 40. Likewise, a contact layer 52 is provided in the second interlayer insulating layer 50 to connect the impurity region 48 to a wiring layer 60.

According to the semiconductor device 300 of the embodiment, compared with the semiconductor device 1000 of the related art shown in FIGS. 25A and 25B, the contact area between the semiconductor and the insulator can be increased. This is because, when the sum of the overlaid area between the gate insulating layer 22 of the semiconductor device 300 and the first semiconductor layer portion 10 and the overlaid area between the gate insulating layer 42 and the second semiconductor layer portion 34 is approximately the same as the overlaid area between the semiconductor layer portion 510 and the gate insulating layer 502 in the semiconductor device 1000, in the semiconductor 300, the surface area can be increased by the amount that they are isolated from the plurality of semiconductor layer portions 10 and 34. Therefore, the contact area being in contact with the insulating material can be increased, and thus, as in the embodiments described above, the heat dissipation capacity can be improved. As a result, a semiconductor device that has the similar effect as the semiconductor device 100 of the first embodiment can be provided.

Furthermore, since the plurality of the semiconductor layer portions 10 and 34 are laminated with the interlayer insulating layer 30 interposed therebetween, the present embodiment has an advantage that the element area can be decreased.

Method of Manufacturing Semiconductor Device

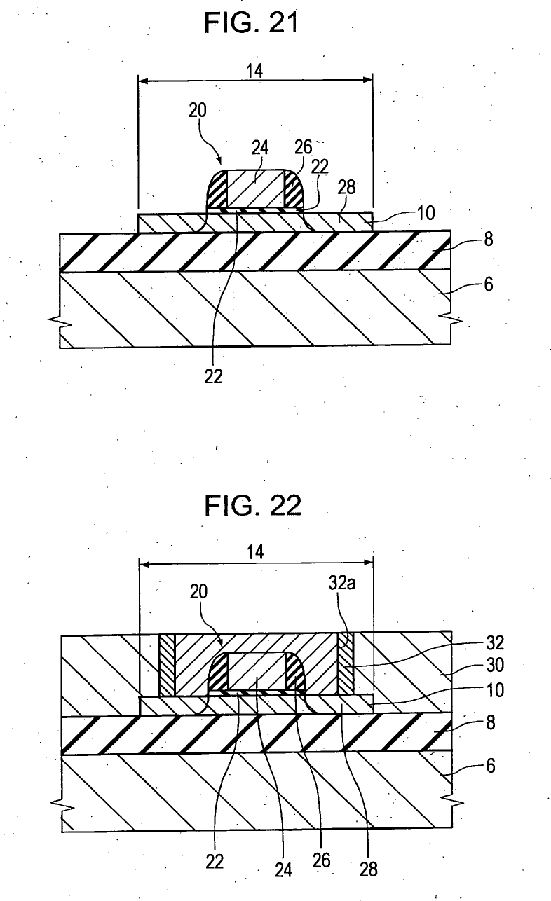

Next, a method of manufacturing the semiconductor device shown in FIG. 20 will be described with reference to FIGS. 21 to 24. FIGS. 21 to 24 are cross-sectional views schematically showing the semiconductor device according to the embodiment. It is noted that the detailed description on the process will be omitted if it can be performed by the same process as in the method of manufacturing the semiconductor device of the first embodiment.

First, as shown in FIG. 21, a first semiconductor layer portion 10 in which an element formation region 14 is defined is formed on an insulating layer 8 which is provided on a supporting substrate 6. Thereafter, by performing the processes of the first embodiment, a first transistor 20 can be formed.

Next, as shown in FIG. 22, a first interlayer insulating layer 30 is formed on the first semiconductor layer portion 10 and the insulating layer 8 which is exposed so as to overlay the first transistor 20. The first interlayer insulating layer 30 can be formed of, for example, a silicon oxide layer, or the like. Thereafter, a contact hole 32a is formed in the first interlayer insulating layer 30 by a well-known technology, and the contact hole 32a is filled by a conductive layer, thereby forming a contact layer 32. The contact layer 32 electrically connects the first transistor 20 and a second transistor 40 each other which will be formed by a later process.

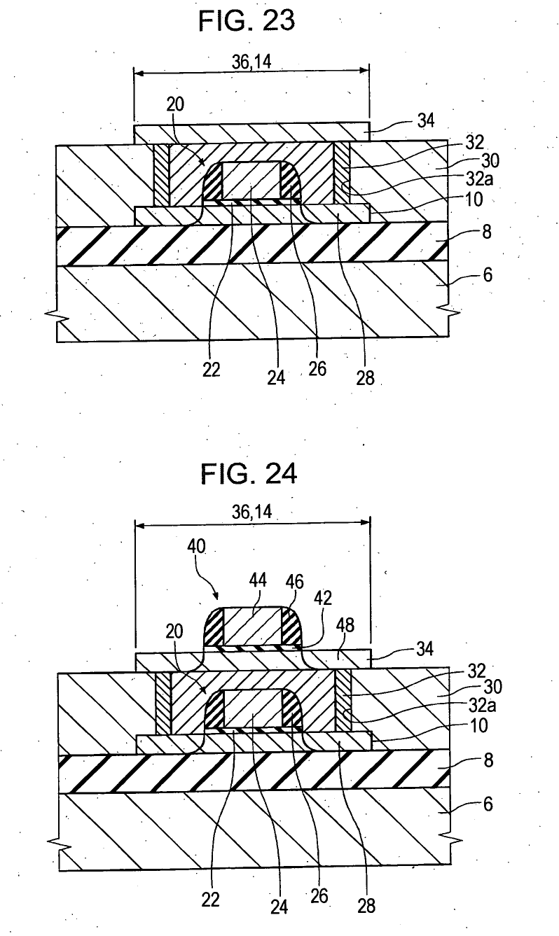

Next, as shown in FIG. 23, a semiconductor layer (not shown) is formed on the first interlayer insulating layer 30. The semiconductor layer can be formed of a poly-crystal silicon layer, a single-crystal layer, or the like. The poly-crystal silicon layer can be formed by a well-known technology. If necessary, by patterning the semiconductor layer, a second semiconductor layer portion 34, which is an element formation region 36, is formed. Also, as an example of forming the semiconductor layer, there is a method (micro-Czochralski technique) in which, first, a recess (not shown) is formed in a predetermined region of the first interlayer insulating layer 30, and an amorphous silicon layer is formed on the first interlayer insulating layer 30 including the recess, and a laser light is radiated, thereby forming a single-crystal layer. According to the method, there is an advantage that the single-crystal silicon layer can be formed only in a desired region, and thus the patterning process of defining the element formation region 36 is not needed.

Next, as shown in FIG. 24, by performing the same processes as in the embodiments described above on the second semiconductor layer portion 34, a gate insulating layer 42, a gate electrode 44, aside wall insulating layer 46, and an impurity region 48 are formed to form a second transistor 40.

Next, as shown in FIG. 20, a second interlayer insulating layer 50 is formed so as to overlay the second transistor 40. The second interlayer insulating layer 50 may be made of the same material as the first interlayer insulating layer 30. Thereafter, a contact layer 52 is provided in the first interlayer insulating layer 50, and a wiring layer 60 having a desired pattern is formed on the contact layer 52, thereby manufacturing the semiconductor device 300 of the embodiment.

Next, the effects of the semiconductor device according to the embodiment will be described with reference to experimental examples.

### Experimental Embodiment

Semiconductor Device of Experimental Embodiment

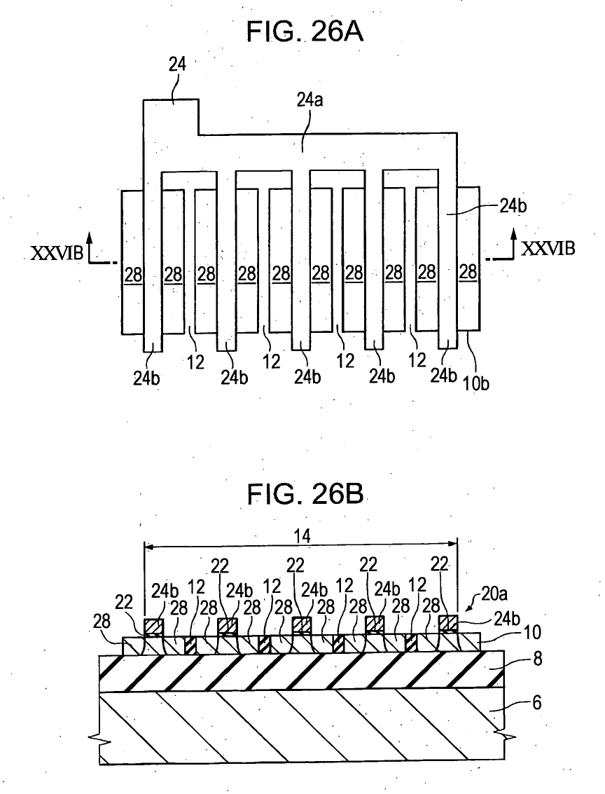

In the present embodiment, a semiconductor device 100 having a structure shown in FIGS. 26A and 26B is implemented. FIG. 26A shows the positional relationship between a semiconductor layer portion 10 and a gate electrode 25 in the semiconductor device 100 of the present embodiment. FIG. 26B is a cross-sectional view taken along the line XXVIB-XXVIB of FIG. 26A. In the present embodiment, as shown in FIG. 26A, the gate electrode 24 is assumed to have a shape having a main axis portion 24a and a branch portion 24b bifurcating so as to be orthogonal to the longitudinal direction of the main axis portion 24a.

Since an isolation insulating layer 12 composed of a silicon oxide layer is formed in an element formation region 14, the element formation region 14 has a structure in which a plurality of p-type silicon layers 10b isolated in island-shapes and the isolation insulating layer 12 are alternately disposed. The isolation insulating layer 12 is provided in a direction crossing the longitudinal direction of the main axis portion 24a of the gate electrode 24 (in a direction parallel to the branch portion 24b). An n-channel type transistor 20a is formed at each of the silicon layers 10b. The transistor 20a includes a gate insulating layer 22 that is a thermal oxidation film and has a thickness of 7 nm, a gate electrode that is made of poly-silicon and becomes the branch portion 24b, and an N-type impurity region 28 that becomes a source or drain region. The gate electrode 24b in each transistor 20a is, in the semiconductor device of the present embodiment, formed of one gate electrode 24, and a plurality of the transistors 20a function as a single transistor 20.

In the present embodiment, five semiconductor devices are formed, all having gate lengths of 1 μm and each having a gate width of 40, 60, 80, 100, and 120 μm, respectively.

Semiconductor Device of Comparative Example

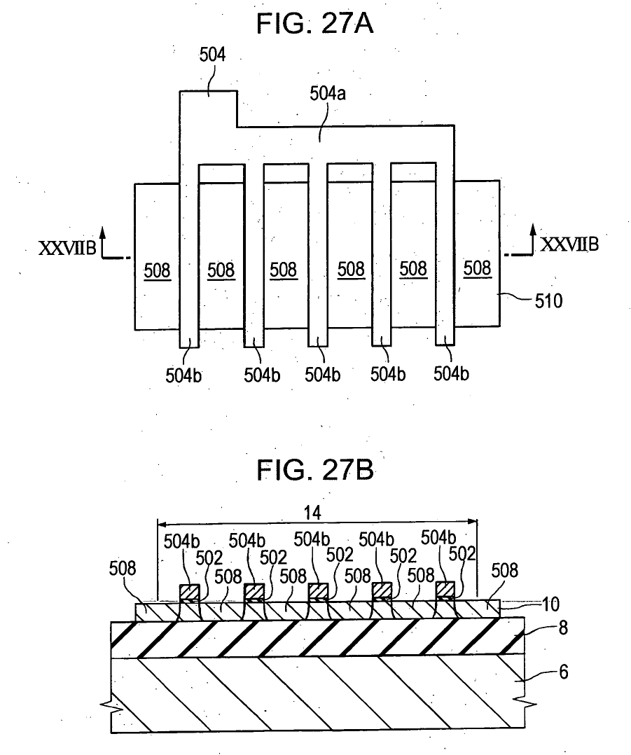

Next, as a semiconductor device according to a comparative example, a semiconductor device having a structure shown in FIGS. 27A and 27B is implemented. FIG. 27A is a plan view schematically showing the positional relationship between a gate electrode 504 and a semiconductor layer portion 10, and FIG. 27B is a cross-sectional view taken along the line XXVIIB-XXVIIB of FIG. 27A. As is apparent from FIG. 27, the only difference between the semiconductor device of the comparative example and that of the embodiment is that the isolation insulating layer 12 is not provided in the comparative example. In the comparative example, a transistor 500 includes a plurality of transistors 500a each of which has a branch portion 512b serving as the gate electrode. Similarly to the embodiment, five semiconductor devices are formed, all having gate lengths of 1 μm and each having a gate width of 40, 60, 80, 100, and 120 μm in each of the transistors 500a, respectively.

Measurement and Evaluation

In the embodiment and comparative example, the drain current (Ids) was measured when the gate voltage (Vgs) was 2 V, drain voltage (Vds) was 2.5 V, and the source voltage (Vs) was 0 V.

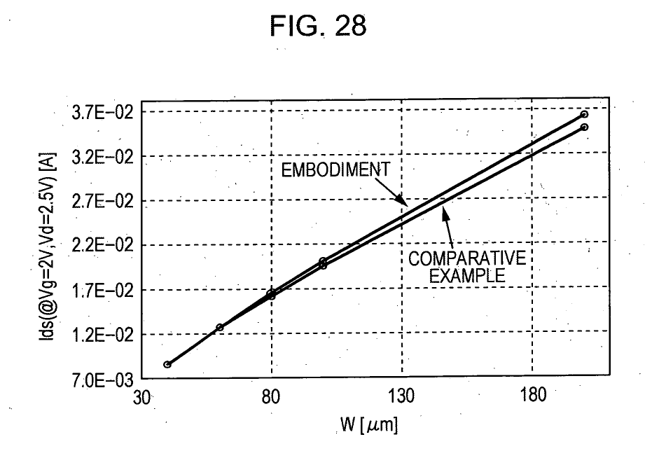

The measurement result is shown in FIG. 28. In FIG. 28, the horizontal axis indicates the gate width, and the vertical axis indicates the drain current [A]. As can be seen from FIG. 28, it was realized that the drain current of the semiconductor device of the embodiment became greater compared with the drain current of the comparative example. The reason is presumably that the heat dissipation capacity is improved by increasing the contact area between the silicon layer and the silicon oxide layer, and thus the current drive capability by self-heating can be prevented from being deteriorated. Also, it was realized that the difference in the drain current between the embodiment and the comparative example became larger as the gate width became larger. The reason is that as the gate width becomes larger, the heat dissipation capacity of an element according to the increase in the contact area becomes greater, but self-heating by the current increase occurs by the amount beyond the increased heat dissipation capacity.

By the above described embodiments, the effects of the invention can be confirmed.

It is noted that the invention is not limited to the embodiments described above, but various modifications and changes can be made within the scope and sprit of the present invention. Also, at least two or more among the first to third embodiments may be combined. For example, although the case in which the isolation insulating layer 12 is provided in the semiconductor layer portion 10 has been described in the first embodiment, the shape of the insulating layer 8 may be that of the insulating layer 8 having the protrusion 8a in the semiconductor device 100.

Also, even though the recess 12a is formed on the semiconductor layer portion 10 and the isolation insulating layer 12 is formed by filling the insulating material into the recess 12a in the embodiments described above, the invention is not limited thereto. For example, the isolation insulating layer 12 may be a layer formed by the LOCOS technique. In this case, the isolation insulating layer 12 is formed by oxidizing the surface of the semiconductor layer portion 10, and as the result of the surface oxidization, the surface of the semiconductor layer portion 10 ends up having a recess shape. The recess shape corresponds to the recess portion 12a of the invention.

The entire disclosure of Japanese Patent Application Nos. 2004-355733, filed Dec. 8, 2004 and 2005-262212, filed Sept. 9, 2005 are expressly incorporated by reference herein.

What is claimed is:

1. A semiconductor device comprising:
a semiconductor layer portion provided on an insulating layer, the semiconductor layer portion becoming an element formation region;
a gate insulating layer provided on the semiconductor layer portion;
a gate electrode provided on the gate insulating layer; and
an impurity region provided in the semiconductor layer portion, the impurity region becoming a source or drain region,
wherein the semiconductor layer portion is provided with a recess and an isolation insulating layer formed by filling the recess with an insulating material.

2. The semiconductor device according to claim 1,
wherein the insulating layer has a protrusion.

3. A semiconductor device comprising:
a semiconductor layer portion provided on an insulating layer, the semiconductor layer portion becoming an element formation region;
a gate insulating layer provided on the semiconductor layer portion;
a gate electrode provided on the gate insulating layer; and
an impurity region provided in the semiconductor layer portion, the impurity region becoming a source or drain region,
wherein the insulating layer has a protrusion on a surface being in contact with the semiconductor layer portion.

4. The semiconductor device according to claim 3,
wherein the insulating layer is provided on a predetermined substrate body, and
the insulating layer has a protrusion on a surface being in contact with the substrate body.

5. A semiconductor device comprising:
a first semiconductor layer portion provided on an insulating layer;
a first insulating gate type field effect transistor provided on the first semiconductor layer portion;
a first interlayer insulating layer provided at least on the first insulating gate type field effect transistor;
a second semiconductor layer portion provided on the first interlayer insulating layer;
a second insulating gate type field effect transistor provided on the second semiconductor layer portion; and
a second interlayer insulating layer provided on the second insulating gate type field effect transistor,
wherein the sum of surface areas of the first semiconductor layer portion and the second semiconductor layer portion is larger than the surface area of one continuous semiconductor layer in another semiconductor device having an insulating gate type field effect transistor in an element formation region formed of the continuous semiconductor layer.

6. The semiconductor device according to claim 5,
wherein at least one of the first semiconductor layer portion and the second semiconductor layer portion is provided with a recess and an isolation insulating layer made by filling an insulating material in the recess.

7. The semiconductor device according to claim 5,
wherein the insulating layer has a protrusion on a surface being in contact with the semiconductor layer portion.

8. The semiconductor device according to claim 1,
wherein the recess is provided in a line shape and crosses the longitudinal direction of the gate electrode.

9. The semiconductor device according to claim 8,
wherein the recess has a depth reaching the insulating layer.

10. The semiconductor device according to claim 1,
wherein the recess is provided in a line shape and in a direction not crossing the longitudinal direction of the gate electrode.

11. The semiconductor device according to claim 1,
wherein the recess is provided in a matrix.

12. The semiconductor device according to claim 2,
wherein the protrusion is provided in a line shape and crosses the longitudinal direction of the gate electrode.

13. The semiconductor device according to claim 2,
wherein the protrusion is provided in a line shape and does not cross the longitudinal direction of the gate electrode.

14. The semiconductor device according to claim 2,
wherein the protrusion is provided in a matrix.
